(19) United States
(12) Patent Application Publication
(10) Pub. No.: US 2025/0283937 A1
(43) Pub. Date: Sep. 11, 2025

(54) SYSTEM AND METHOD OF ADAPTIVE AUTO TUNING OF THERMAL CONTROL SYSTEM FOR DEVICE TESTING

(71) Applicant: Advantest Test Solutions, Inc., San Jose, CA (US)

(72) Inventors: Frankie G. ANTONINI, San Jose, CA (US); Aleksandr MIKUNOV, San Jose, CA (US); Amey SUBHEDAR, San Jose, CA (US)

(21) Appl. No.: 18/600,453

(22) Filed: Mar. 8, 2024

(51) Int. Cl. G01R 31/28; G05B 11/42

(52) U.S. Cl. CPC G01R 31/2874; G05B 11/42

(57) ABSTRACT

Embodiments of the present invention provide an adaptive PID (Proportional-Integral-Derivative) auto-tuning technique that enhances the efficiency and accuracy of tuning thermal control systems for device testing. The disclosed techniques can automatically adjust PID controller values to optimize thermal conditions for devices under test (DUTs) utilizing real-time feedback from temperature probes such as resistance temperature detector (RTD), thermocouple, thermistor and/or electrical semiconductor device such as thermal diode and/or digital temperature bus to temperature sensors. The system supports parallel adjustments across multiple DUT sites, significantly improving tuning throughput. This adaptive approach streamlines the tuning process by minimizing manual intervention and stores the refined PID settings in memory for each test site, ensuring consistent and precise temperature control during testing operations.

### FIELD OF THE INVENTION

Embodiments of the present invention relate to the field of device testing. More specifically, embodiments relate to techniques for tuning thermal control functions of automated test equipment.

### BACKGROUND

A device or equipment under test (DUT) is typically tested to determine the performance and consistency of the device before the device is sold. For example, a DUT can be tested using a large variety of test cases, and the result of the test cases can be compared to an expected output result. When the result of a test case does not match a satisfactory value or range of values, the device can be considered a failed device or outlier, and the device can be binned based on performance parameters, etc.

A DUT is usually tested by automatic or automated test equipment (ATE), or automated test systems (ATS), which may be used to conduct complex testing using software and automation to improve the efficiency of testing. The DUT may be any type of semiconductor device, wafer, or component that is intended to be integrated into a final product, such as a computer, network interface, memory, or other hardware component, such as a solid-state drive (SSD). By removing defective or unsatisfactory chips at manufacture using automated test equipment (ATE) or automated test system (ATS), the quality of the yield can be significantly improved.

Testing often causes DUTs to heat up. Cooling and if required heating systems are therefore utilized to maintain desired temperature set point (TSP). Proportional-Integral-Derivative (PID) controllers are commonly used to regulate these cooling and heating systems, ensuring precise and stable temperature control. The process of tuning PID controllers is critical in maintaining precise and stable temperature control for Devices Under Test (DUTs). This tuning is essential for optimizing cooling systems. Manual tuning involves adjusting these parameters based on operator expertise or through systematic methods such as Ziegler-Nichols, which aims to determine the ultimate gain and oscillation period through experimental adjustments. The Step Response Analysis method applies a step input to observe the system's behavior, aiding in fine-tuning Proportional Gain to a point just before system oscillation to ensure stability.

The tuned PID parameters can be implemented to observe the system's response under various conditions, and the parameters can be fine-tuned to achieve the desired temperature set point (TSP). Unfortunately, manual PID tuning is a time-consuming and labor-intensive process, often requiring trial-and-error adjustments by operators. This process also must be repeated after maintenance is performed, and any time certain test system components are repaired or replaced (e.g., fans, cold plates, heaters, thermal insulation material, etc.). Moreover, manual PID tuning is prone to inconsistencies and human errors, leading to suboptimal performance and potential test failures. Accordingly, what is needed is a flexible tuning process that automatically determines effective PID values and reduces the likelihood of errors introduced by manual interventions.

### SUMMARY

Accordingly, embodiments of the present invention provide an adaptive PID (Proportional-Integral-Derivative) auto-tuning technique that enhances the efficiency and accuracy of tuning thermal control systems for device testing. The disclosed techniques can automatically adjust PID controller values to optimize thermal conditions for devices under test (DUTs) utilizing real-time feedback from temperature probes such as resistance temperature detector (RTD), thermocouple, thermistor and/or electrical semiconductor device such as thermal diode and/or digital temperature bus to temperature sensors. The system supports parallel adjustments across multiple DUT sites, significantly improving tuning throughput. This adaptive approach streamlines the tuning process by minimizing manual intervention and stores the refined PID settings in memory for each test site, ensuring consistent and precise temperature control during testing operations.

According to one disclosed embodiment, a test system for device testing is disclosed. The test system includes a test board comprising a plurality of test sites operable to receive a plurality of devices under test (DUTs) for testing, and a cooling and heating system comprising a PID (Proportional-Integral-Derivative) controller, wherein the PID controller is operable to automatically perform an adaptive PID tuning process to test the plurality of DUTs operable to be disposed in the test sites.

According to some embodiments, the PID controller is further operable to automatically adjust PID controller values for the plurality of DUTs based on a response measurement to achieve a target performance metric based on adjusted PID controller values.

According to some embodiments, the PID controller is further operable to store the adjusted PID controller values in a memory associated with a respective test site.

According to some embodiments, the adaptive PID tuning process includes: accessing a set of initial PID controller values, applying the set of initial PID controller values to test the plurality of DUTs and to determine responses of the plurality of DUTs, adjusting the PID controller values based on the responses of the plurality of DUTs to achieve a predefined performance metric, and storing adjusted PID controller values in a memory associated with the test sites that receives the DUTs during testing.

According to some embodiments, the PID controller values for the plurality of DUTs are tuned in parallel, and the DUTs are tested and tuned independently.

According to some embodiments, the method includes a thermal controller communicatively coupled to the PID controller, the thermal controller is operable to manage temperature conditions of the test board.

According to some embodiments, the thermal controller is further operable to dynamically apply PID values provided by the PID controller.

According to some embodiments, the thermal controller is further operable to perform temperature control using a DUT Temperature Feedback mode that functions to maintain conditions based on a temperature set point (TSP).

According to some embodiments, the DUT Temperature Feedback mode functions to maintain, based on the TSP, at least one of: a DUT temperature, and a thermal test vehicle (TTV) temperature.

According to some embodiments, the thermal controller is further operable to perform temperature control using a heating system such as an Active Thermal Interposer (ATI) Temperature Feedback mode that functions to maintain an ATI temperature based on a temperature set point (TSP).

According to a different embodiment, an apparatus for tuning PID controller values is disclosed. The apparatus includes a memory for storing PID controller values, a temperature probe operable to determine a thermal response of a DUT to the PID controller values, and a PID controller operable to execute an adaptive PID tuning process including adjusting and storing the PID controller values based on the thermal response and test criteria.

According to some embodiments, the apparatus further includes a thermal controller communicatively coupled to the PID controller, the thermal controller is operable to manage temperature conditions within the test environment.

According to some embodiments, the thermal controller is further operable to dynamically apply PID values provided by the PID controller.

According to some embodiments, the thermal controller is further operable to perform temperature control using a DUT Temperature Feedback mode that functions to maintain DUT thermal conditions based on a temperature set point (TSP).

According to some embodiments, the DUT Temperature Feedback mode functions to maintain, based on the TSP, at least one of: DUT temperature, and thermal test vehicle (TTV).

According to some embodiments, the thermal controller is further operable to perform temperature control using an Active Thermal Interposer (ATI) Temperature Feedback mode that functions to maintain an ATI temperature based on a temperature set point (TSP).

According to another embodiment, a method of automatically tuning PID (Proportional-Integral-Derivative) controller values for a tester system is disclosed. The method includes accessing a set of initial PID controller values for testing a device under test (DUT), applying the set of initial PID controller values to test the DUT and determine a response of the DUT to the testing, adjusting the initial PID controller values based on the response of the DUT to achieve a predefined performance metric and to generate adjusted PID controller values, and storing the adjusted PID controller values in a memory associated with a DUT test site that receives the DUT during the testing.

According to some embodiments, applying the set of initial PID controller values to test the DUT and to determine a response of the DUT includes testing a plurality of DUTs in parallel to determine a plurality of DUT responses.

According to some embodiments, the method includes testing the DUT using a DUT Temperature Feedback mode that functions to maintain DUT thermal conditions based on a temperature set point (TSP).

According to some embodiments, the method includes testing the DUT using an Active Thermal Interposer (ATI) Temperature Feedback mode that functions to maintain an ATI temperature based on a temperature set point (TSP).

### BRIEF DESCRIPTION OF THE DRAWINGS

The accompanying drawings, which are incorporated in and form a part of this specification, illustrate embodiments of the invention and, together with the description, explain the principles of the invention:

FIG. 1 depicts an exemplary test board (e.g., a Burn-in Interface Board BIB or System Level Test SLT Test Interface Board TIB) including multiple test sites for receiving DUTs to be tested using a thermal controller that operates a PID controller for performing thermal control functions according to embodiments of the present invention.

FIG. 2 is a graph depicting exemplary temperature measurements and set points of 6 different DUTs performing PID autotuning according to embodiments of the present invention.

FIG. 3 depicts four exemplary test boards of a test system, each test board having six test sites for performing parallel adaptive PID tuning to determine PID values of DUTs disposed in the test sites during testing according to embodiments of the present invention.

FIG. 4 is a table depicting results of an exemplary PID autotuning test sequence across four phases for three test sites according to embodiments of the present invention.

FIG. 5 is a graph depicting the first phase of an exemplary automatic PID tuning process including a time sensitive ramp up according to embodiments of the present invention.

FIG. 6 is a graph depicting the second phase of an exemplary automatic PID tuning process that includes a time sensitive stabilization at high temperature according to embodiments of the present invention.

FIG. 7 is a graph depicting the third phase of an exemplary automatic PID tuning process that includes a time sensitive cool down according to embodiments of the present invention.

FIG. 8 is a graph depicting the fourth phase of an exemplary automatic PID tuning process that includes a full thermal loop (ramp up, stabilization at high temperature, and cool down) according to embodiments of the present invention.

FIG. 9 is a flowchart depicting an exemplary sequence of computer implemented steps of a process for automatically tuning a PID controller for performing thermal control during device testing according to embodiments of the present invention.

FIG. 10 is a flowchart depicting an exemplary sequence of computer implemented steps of a process for automatically tuning a PID controller using multiple test phases according to embodiments of the present invention.

FIG. 11 is a flowchart depicting an exemplary sequence of computer implemented test phases of a process for automatically tuning a PID controller using four test phases according to embodiments of the present invention.

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

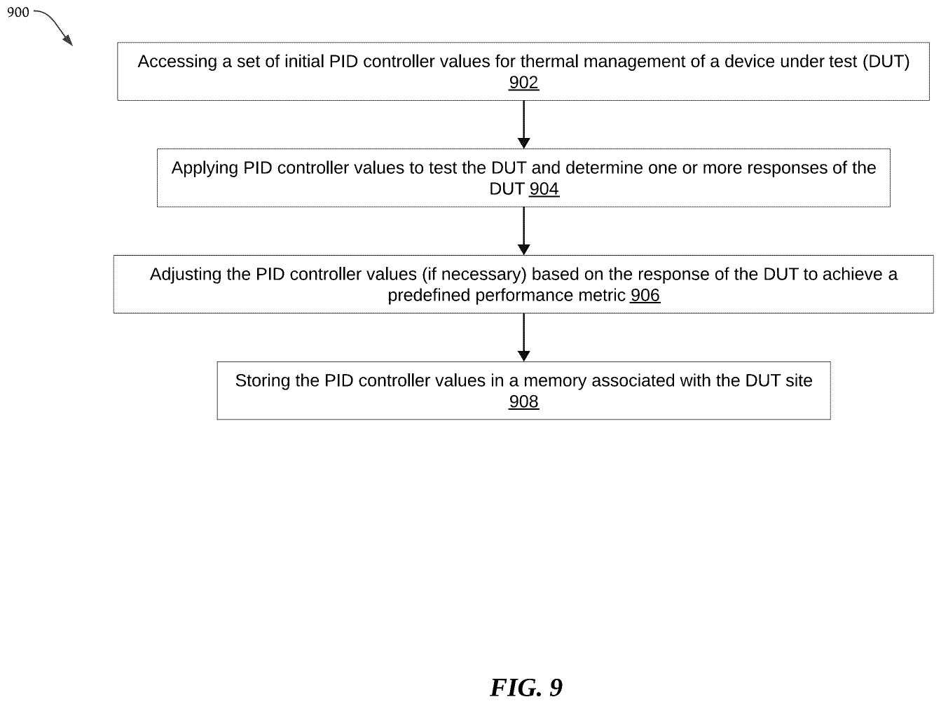

Portions of the detailed description that follows are presented and discussed in terms of a method. Although steps and sequencing thereof are disclosed in a figure (e.g., FIGS. 9-11) herein describing the operations of this method, such steps and sequencing are exemplary. Embodiments are well suited to performing various other steps or variations of the steps recited in the flowchart of the figure herein, and in a sequence other than that depicted and described herein.

Some portions of the detailed description are presented in terms of procedures, steps, logic blocks, processing, and other symbolic representations of operations on data bits that can be performed on computer memory. These descriptions and representations are the means used by those skilled in the data processing arts to convey the substance of their work most effectively to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, parameters, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “associating,” “identifying,” “encoding,” “labeling,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some embodiments may be described in the general context of computer-executable instructions, such as program modules, executed by one or more computers or other devices. Generally, program modules include routines, algorithms, programs, objects, components, data structures, etc. that perform particular tasks or implement particular abstract data types. Typically, the functionality of the program modules may be combined or distributed as desired in various embodiments.

### Adaptive Per-Site Autotuning of PID Values for Thermal Control During Device Testing

Embodiments of the present invention provide an adaptive PID (Proportional-Integral-Derivative) auto-tuning technique that enhances the efficiency and accuracy of tuning thermal control systems for device testing. The disclosed techniques can automatically adjust PID controller values to optimize thermal conditions for devices under test (DUTs) utilizing real-time feedback from temperature probes. The system supports parallel adjustments across multiple DUT sites, significantly improving tuning throughput. This adaptive approach streamlines the tuning process by minimizing manual intervention and stores the refined PID settings in memory for each test site, ensuring consistent and precise temperature control during testing operations.

Embodiments described herein provide an adaptive per-site tuning solution for thermal control of System Level Test (SLT) and Burn-In systems, thereby enhancing thermal performance and consistency while reducing test system power consumption. PID parameters can be optimized for thermal performance, stability, and power consumption to significantly improve the overall efficiency of the testing process, as well-tuned PID controller values reduce the power consumption of SLT and Burn-In Systems when maintaining DUTs at a desired setpoint temperature. Advantageously, scheduled tool downtime during periodic maintenance or repair is significantly reduced while the process is streamlined for efficiency.

Some embodiments of the present invention utilize enhanced parallel test capabilities of advanced site test software (e.g., Advantest ActivATE™ Test Management Software) to facilitate simultaneous auto-tuning of PID controller values for up to 120 devices simultaneously in a 20-slot configuration (six DUTs per slot), for example.

According to some embodiments, the auto-tuning process involves four distinct phases, each tailored to address specific temperature dynamics, although additional or fewer testing phases can be used within the scope of the invention. Adoption of a specific PID parameter set typically occurs when the target transition time is achieved twice consecutively in each of Phases 1-4. Once the autotuning process is complete, the PID values are stored in memory and can be reused for future testing. For example, PID values can be stored in local memory at each test site or in a network storage location, according to embodiments.

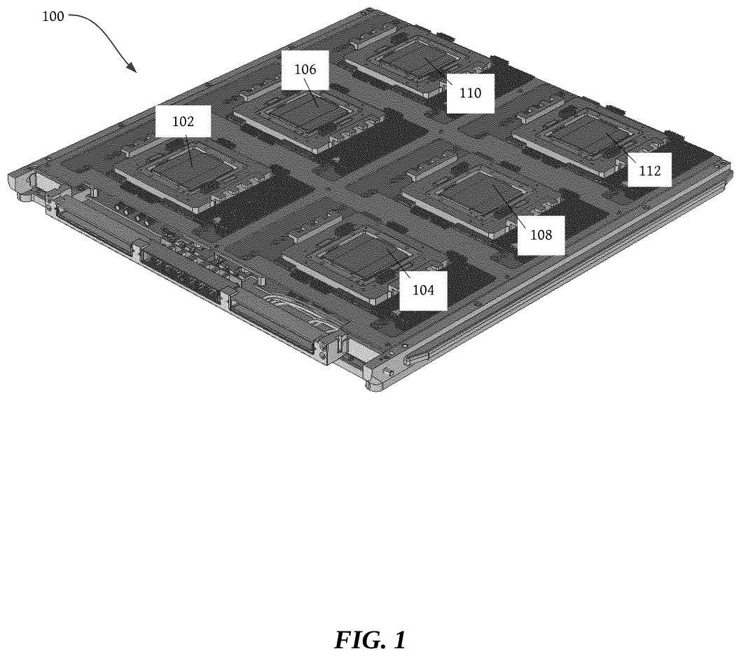

FIG. 1 depicts an exemplary test board 100 (e.g., a Burn-in Interface Board BIB or System Level Test SLT Test Interface Board TIB) including multiple test sites for receiving devices under test (DUTs) to be tested using a thermal controller (TC) that operates a PID controller to perform thermal control functions according to embodiments of the present invention. The PID controller can be tuned automatically (“autotuning”) using a computer implemented process that ensures that PID controller values are appropriately adjusted for each individual DUT in real-time without requiring any manual interaction of an operator. For example, optimal PID Controller values for SLT and Burn-In testing can be automatically generated by a test that aims to set PID values that maintain a DUT, TTV, or ATI temperature at a set point within a time limit (ramp rate). Another aspect of the tuning process can include a stabilization requirement enforced within a temperature guard band, as discussed in more detail below.

The embodiment depicted in FIG. 1 can be used to autotune multiple DUTs in parallel. DUTs 102, 104, 106, 108, 110, 112 are disposed in respective test sites on test board 100 and can be automatically tuned at the same time to determine PID values. The PID values can be stored in non-volatile memory thereof or at a remote storage location, for example. After the PID values are determined and adopted, DUTs 102, 104, 106, 108, 110, 112 are tested by an automated test equipment (ATE) or automated test system (ATS), and thermal control is performed at least in part according to the PID values during testing. For example, thermal control functions can be performed by the thermal controller according to PID values provided by the PID controller to control cooling from a fan or cold plate, for example, and if necessary heating by an active thermal interposer (ATI).

According to some embodiments, PID values are determined for each test site using a four-phase testing method. Phase 1 involves initiating a transit time for the temperature rise to assess the dynamic response of the system. This phase serves to understand how quickly and effectively the thermal control system can react to an increase in temperature. Phase 2 performs an extended temperature rise before allowing the device to stabilize within guard band at the set temperature to evaluate the steady-state performance and ability to maintain a consistent temperature under test conditions. In Phase 3, the process involves inducing a transit time for the temperature fall from the stabilized set temperature, providing insight into the system's cooling efficiency and how it handles decreases in thermal conditions. Phase 4 focuses on maintaining stability at a reduced temperature during a complete thermal cycle, testing the system's ability to sustain temperatures after falling back to initial thermal conditions.

According to some embodiments, four PID regions per site are available to drive:
1. The ATI Primary heater.
2. The ATI Secondary heater (if available).
3. Pulse Width Modulation (PWM) Fan or Proportional Valve Opening (PVO); Cold Plate to keep the ATI heater(s) at the optimum average power.
4. Dormant PID to protect hardware.

To determine if the system has passed or failed a particular test, acceptable performance metrics can be set according to criteria including key success metrics such as achieving a target set point temperature within the specified time constraint (Transit Time limit), achieving a target set point temperature while maintaining thermal stability with a prescribed temperature range (e.g., Guard-band), and keeping the fan or Cold Plate temperature operating limit.

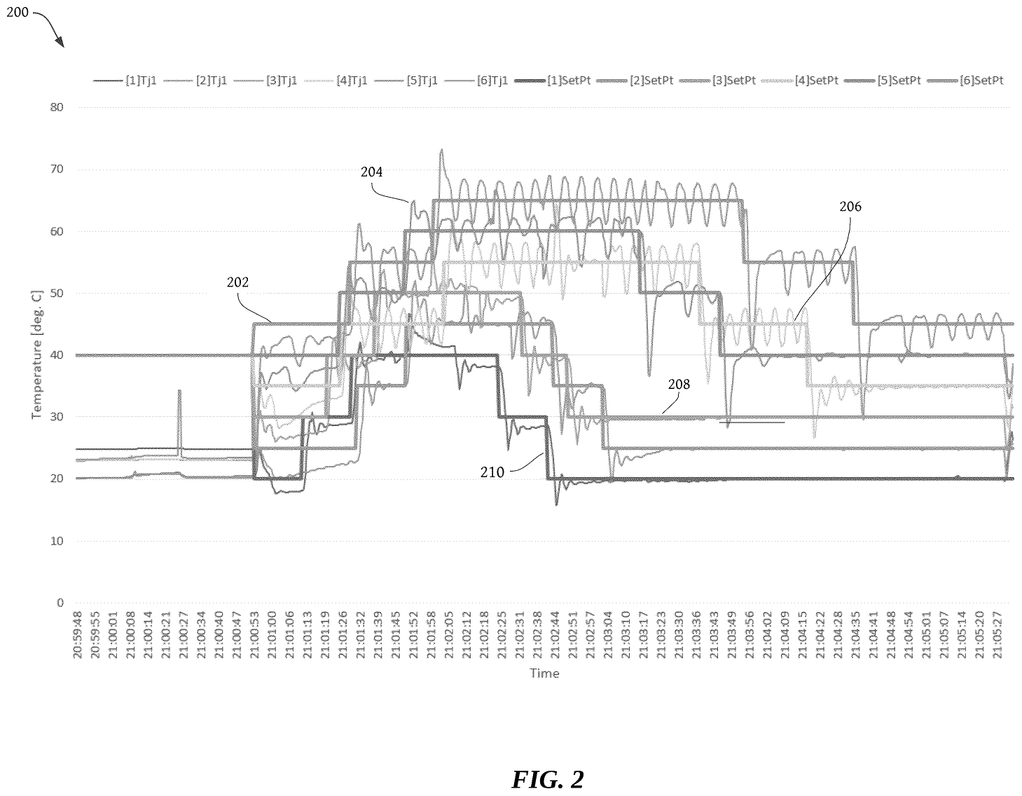

FIG. 2 is a graph 200 depicting exemplary temperature measurements and temperature set points (TSPs) of 6 different DUTs (e.g., DUTs 102, 104, 106, 108, 110, 112) performing PID autotuning to determine PID values that efficiently reach DUTs temperature set point (TSP) within transit time limit and within guard-band according to embodiments of the present invention. In the example of FIG. 2, the actual measured temperatures 202, 204, 206, 208, 210 rise and fall to match the corresponding TSP during PID autotuning according to embodiments of the present invention. Each test can be considered a success, or a failure based on the specified acceptance criteria. For example, a test can be considered a failure if the target transit time is not satisfied, if the measured temperature falls outside of a guard-band, etc. The tests can be repeated iteratively using different PID values to determine values that can improve device testing throughput and efficiency by improving thermal management during testing without manual operator intervention or adjustment.

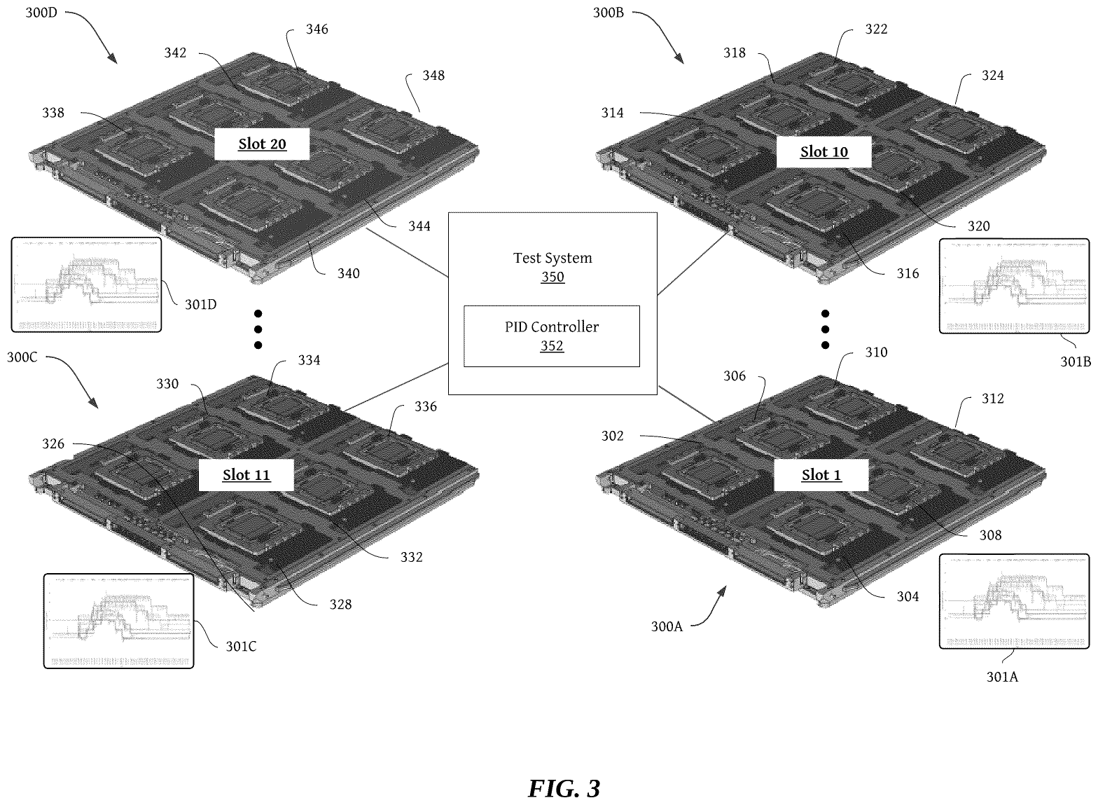

FIG. 3 depicts four exemplary test boards 300A, 300B, 300C, 300D (“slots”) of a test system 350, each test board having six test sites for performing parallel adaptive PID tuning of DUTs disposed in the test sites during testing according to embodiments of the present invention. Test system 350 in this example includes 20 test boards (e.g., a Burn-in Interface Board BIB or System Level Test SLT Test Interface Board TIB) in total facilitating parallel and independent PID autotuning for up to 120 DUTs simultaneously. Scaling the test system in this way provides a significant increase in testing throughput and efficiency for high-volume semiconductor manufacturing environments. Test system 350 can dynamically adjust PID settings for each DUT using PID controller 352, ensuring precise thermal management and optimal testing conditions across all test sites, thereby streamlining the PID autotuning process while minimizing manual intervention and maximizing testing accuracy. PID values 301A, 301B, 301c, and 301D generated by PID autotuning can be stored locally in memory at each test site 302-348.

In the example of FIG. 3, Slot 1 (300A) features six (for example) individual test sites 302, 304, 306, 308, 310, 312. Slot 10 (300B) includes test sites 314, 316, 318, 320, 322, 324. Slot 11 (300C) includes test sites 326, 328, 330, 332, 334, 336. Slot 20 (300D) includes test sites 338, 340, 342, 344, 346, 348. All the test sites support parallel PID autotuning to achieve optimal thermal management and device performance according to predetermined criteria, thereby enhancing the system's testing capacity and operational efficiency.

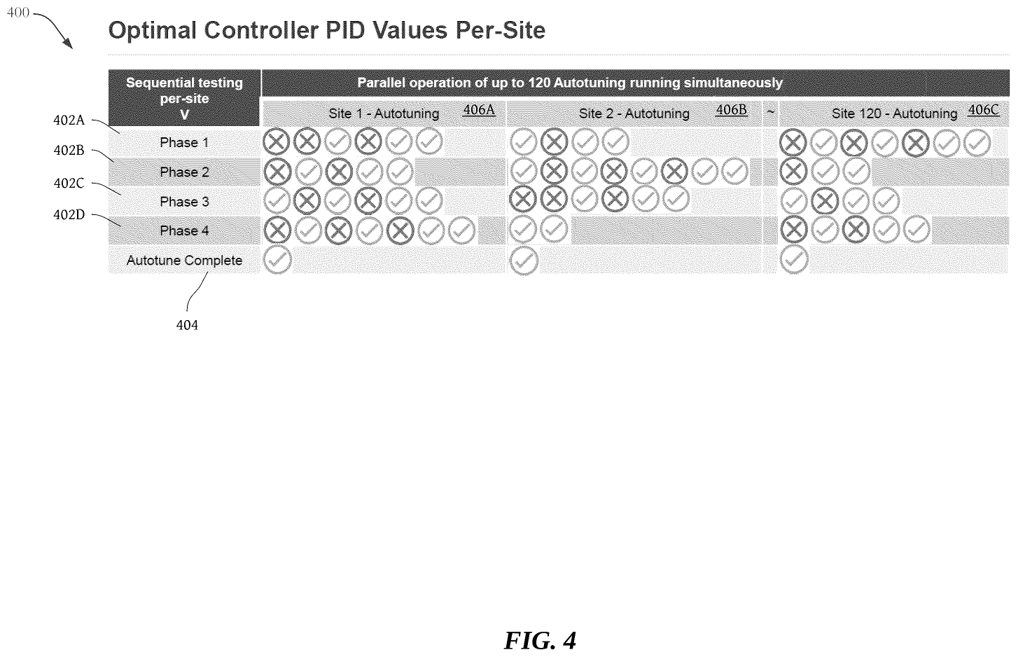

FIG. 4 is a table depicting results of an exemplary PID autotuning test sequence 400 across four phases 402A, 402B, 402C, 402D for three test sites 406A, 406B, 406C according to embodiments of the present invention. In each phase, a test site undergoes tests to adjust PID controller values aiming for two consecutive successful outcomes to progress to the next phase. Phase 1 (402A) focuses on initial temperature adjustment (ramp up transit test time), Phase 2 (402B) stabilizes these adjustments within guard-band temperature, Phase 3 (402C) refines the adjustments under falling temperature conditions (cool down transit time), and Phase 4 (402D) confirms the adjustments using a full thermal cycle with further stability testing. A site is labeled “autotune complete” after passing two consecutive tests in Phase 4 (402D), indicating that optimal PID settings have been achieved for that site based on predetermined criteria (transit time measured within limit, stability time measured within guard-band temperature, fan or cold plate temperature within operation limit).

The exemplary test sequence 400 illustrates the iterative process of autotuning PID controller values according to embodiments. Initially, in Phase 1 (402A), the site experiences a sequence of outcomes: fail, fail, pass, fail, and then succeeds twice consecutively, indicating that the system has adjusted to achieve the desired response and is ready to move to the next phase. In Phase 2 (402B), the site produces an initial failure, followed by a pass, followed by another fail and then two consecutive passes. In Phase 3 (402C), the site is first successful, followed by a failure, followed by another success, then a failure, and then two consecutive passes. In Phase 4 (402D), the site produces a failure, followed by a success, a failure, a success, a failure, and two consecutive passes to complete the autotune. At this point, Site 1 autotuning 406A is marked complete 404 and the successful PID values can be stored at the test site (or at a remote storage location, data center, etc.). Site 2 autotuning 406B and Site 120 autotuning 406C are completed in the same fashion (the test sequence results of Sites 3-119 are not depicted in this example).

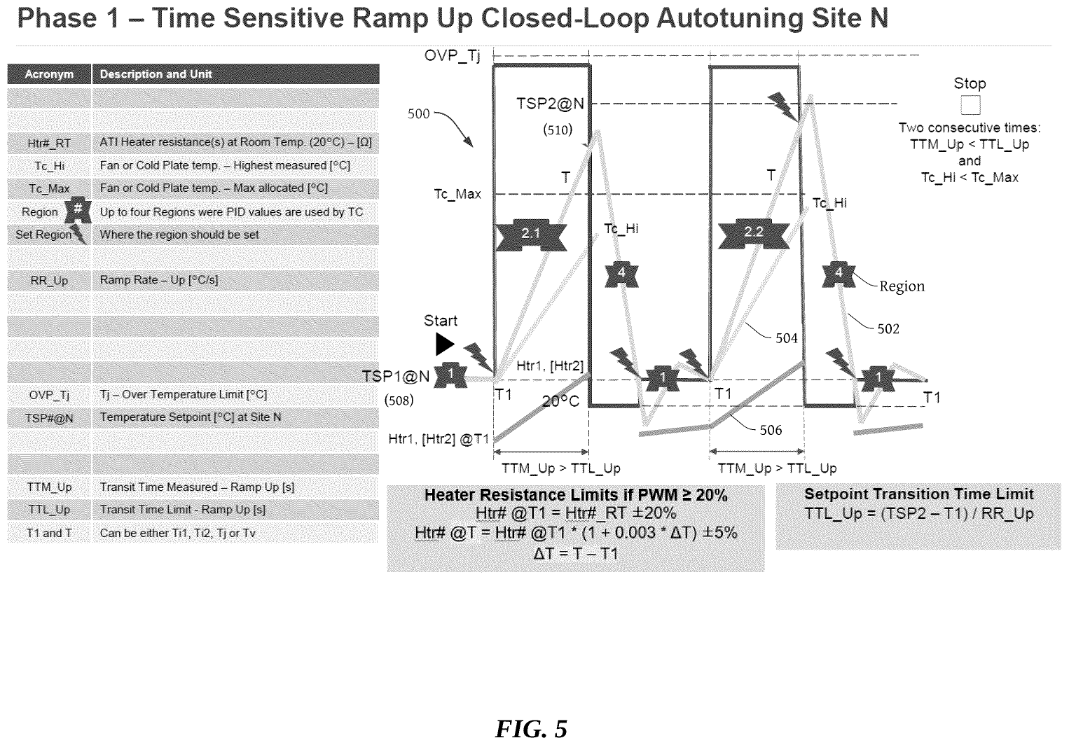

FIGS. 5-8 are graphs depicting exemplary test conditions and measurements of the phases of an automatic PID controller tuning process according to embodiments of the present invention. Each phase is considered complete when two consecutive tests pass all requirements of the test phase. The test process generally aims to maintain test site temperatures (e.g., DUT, TTV, or ATI temperatures) as close as possible to a set point temperature (TSP) within a transit time limit based upon a ramp rate [° C./s], in some cases followed by a return to a guard-band temperature (e.g., a gross guard band and a fine guard band). When the phases of the tuning sequence are complete, the PID controller values for STL and Burn-In solutions can be saved in memory at the test site, for example.

According to some embodiments, each test phase includes up to 4 test regions per test site for driving heating and/or cooling elements according to assigned PID values. The PID regions typically include controlling the ATI Primary heater, the ATI Secondary heater, a PWM Fan or PVO Cold Plate to keep the ATI heater(s) at the optimum average power, and a redundant backup PID to protect hardware. Default or initial PID values can be included for each region and stored in memory of the thermal controller at the test site. Once modified, default/initial PID values can be restored by executing a factory reset.

The autotuning processes can be automatically repeated after changes at the test site, such as when the ATI and/or thermal interface material (TIM) is replaced, after a fan or cold plate is replaced, after airflow, coolant, or refrigerant temperature set point changes, or after a DUT/TTV power dissipation and/or temperature set point requirement changes.

FIG. 5 is a graph depicting the first phase 500 of an exemplary automatic PID tuning process according to embodiments of the present invention. FIG. 5 represents the initial stage of PID autotuning at a test site, focusing on achieving a controlled and steady temperature rise to assess thermal characteristics (e.g., ramp up speed/transit time) using specific PID values.

Phase 1 has the following test conditions:
1. TTM_Up<TTL_Up (Up Transit Time Measured lower than Up Transit Time Limit)
2. Tc_Hi<Tc_Max (Fan or Cold Plate Temperature Highest measured lower than maximum temperature allocated)
   In Phase 1, only Region #2 PID values can be changed until the ramp up transit time and cooling temperature are within limits two consecutive times. As depicted in FIG. 5, test site temperature (e.g., DUT, thermal test vehicle (TTV), or ATI) 502 begins Phase 1 with temperature set point TSP1 (508) at T1 and quickly rises (region 2.1) to approach TSP2 (510). Test site temperature 502 fails to ramp up to TSP2 (510) within the transit time limit TTM_Up. After test site temperature 502 falls (region 4) and returns to TSP1 508 (region 1), the heater resistance value 506 automatically increases to a higher resistance value to bring test site temperature 502 to the desired set point 510 (region 2.2). Simultaneously, the temperature 504 of the fan or cold plate controlled by the thermal controller is monitored to manage device cooling and prevent overheating within the defined parameters and limitations (e.g., Tc_Max).

The first test condition of Phase 1 specifies a transit time limit (ramp up) TTL_Up for region 2 (e.g., regions 2.1, 2.2). In the Example of FIG. 5, the ramp up transit time measured TTM_Up is completed successfully in region 2.2 within the transit time limit of TTL_Up, where TTL_Up is defined as TSP2−T1 divided by the ramp up rate RR_Up [° C./s].

According to some embodiments, the ATI heater resistance limit for Htr1 and Htr2 if present on the ATI can be automatically determined according to the following equations:

Heater Resistance Limits if Pulse Width Modulation (PWM)≥20%

Htr #@T1=Htr #_RT±20%

Htr #@T=Htr #@T1*(1+0.003*ΔT)±5% with ΔT=T−T1

As depicted in FIG. 5, fan or cold plate temperature 504 increases as the test site temperature 502 and heater resistance value 506 increase. Tc_Max indicates the maximum allocated temperature for the test site, and Tc_Hi marks the highest recorded fan or cold plate temperature 504. In this example, test condition Tc_Hi<Tc_Max is satisfied because the fan or cold plate temperature 504 remains below the maximum temperature Tc_Max.

Phase 1 is complete when two consecutive tests pass all Phase 1 test conditions, and the PID values can be stored in local memory at the test site or ATE. The tuning process then proceeds to Phase 2.

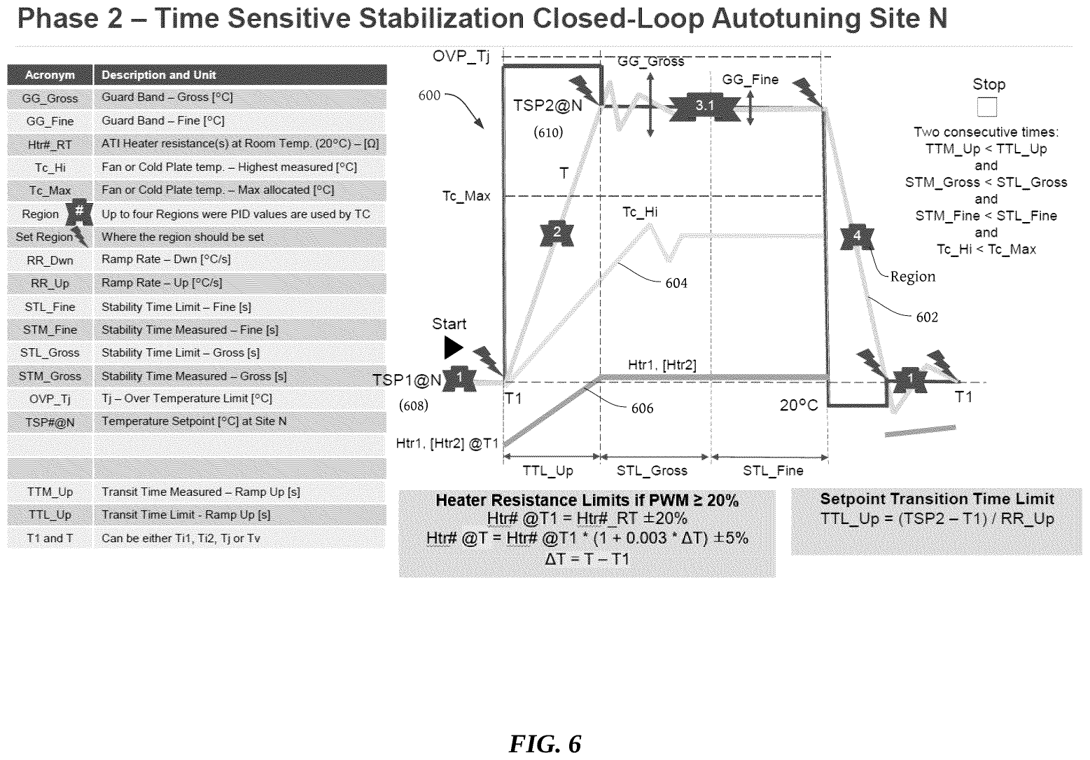

FIG. 6 is a graph depicting the second phase 600 of an exemplary automatic PID tuning process according to embodiments of the present invention. Phase 2 is a time sensitive stabilization test including a period of temperature rise (region 2) controlled by heater resistance value Htr1, [Htr2] if present (606) followed by stabilization at the set temperature (region 3.1). In Phase 2, only Region #3 PID values can be changed until the measured stability time and cooling temperature values are within limits at least two consecutive times.

Phase 2 has the following test conditions:
1. TTM_Up<TTL_Up
2. STM_Gross<STL_Gross (Gross Stability Time Measured lower than Gross Stability Time Limit)
3. STM_Fine<STL_Fine (Fine Stability Time Measured lower than Fine Stability Time Limit)
4. Tc_Hi<Tc_Max
   The gross stability time limit STL_Gross is the maximum time allowed for test site temperature 608 to stabilize within the guard band GG_Gross in region 3.1 after reaching temperature set point 610 from starting temperature set point 608. The fine stability time limit STL_Fine is the maximum time allowed for test site temperature 608 to stabilize within the guard band GG_Fine in region 3.1 after reaching temperature set point 610 from starting temperature set point 608.

The first test condition TTM_Up<TTL_Up specifies that the region 2 time between TSP1 608 and TSP2 610 (TTM_Up) must be less than a threshold transit time limit TTL_Up. The second test condition STM_Gross<STL_Gross specifies that the measured test site temperature 602 must stabilize at TSP2 610 within guard band GG_Gross in a threshold stability time limit STL_Gross. The third test condition STM_Fine<STL_Fine specifies that the measured test site temperature 602 must stabilize at the TSP2 610 within fine guard band GG_fine in a threshold stability time limit STM_Fine. The fourth test condition Tc_Hi<Tc_Max requires that the fan or cold plate temperature 604 remains below the maximum temperature Tc_Max. Once these conditions have been satisfied by two consecutive successful tests, Phase 2 of the tuning process is complete and the tuning process proceeds to Phase 3.

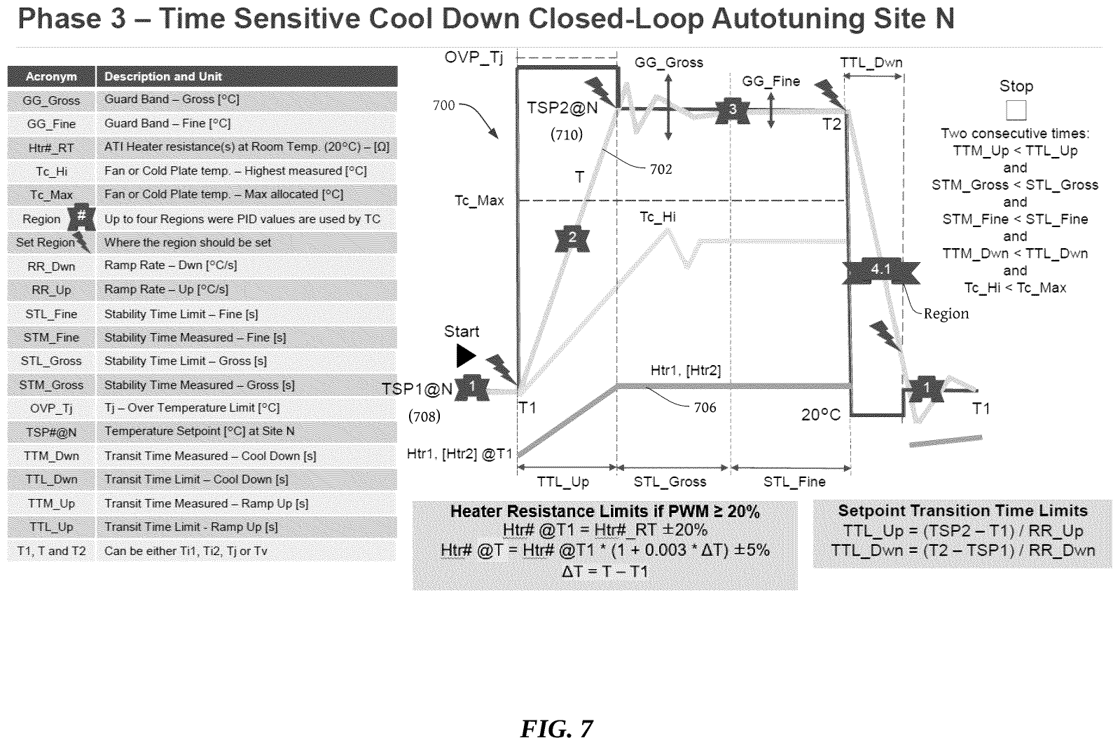

FIG. 7 is a graph depicting the third phase 700 of an exemplary automatic PID tuning process according to embodiments of the present invention. Phase 3 involves a time sensitive cooldown closed-loop test including a period of temperature decrease from a stabilized set temperature controlled using heater resistance values Htr1, [Htr2] if present 706. In Phase 3, only Region #4 PID values can be changed until the cooling down transit time is within the threshold transit time limit at least two consecutive times.

Phase 3 has the follow test conditions:
1. TTM_Up<TTL_Up
2. STM_Gross<STL_Gross
3. STM_Fine<STL_Fine
4. TTM_Dwn<TTL_Dwn (Down Transit Time Measured lower than Down Transit Time Limit
5. Tc_Hi<Tc_Max

Phase 3 begins like Phase 2 of the tuning process. In addition, after test site temperature 702 stabilizes at T2, the measured cool down transit time TTM_Dwn in region 4.1 is determined when test site temperature 702 reaches TSP1 708. Along with the previous requirements of Phase 2, Phase 3 limits the measured transit time TTM_Dwn of region 4.1 to a threshold transit time limit TTL_Dwn, where TTL_Down is defined as T2−TSP1 divided by the ramp down rate [° C./s] of region 4.1. Once these conditions have been satisfied by two consecutive successful tests, Phase 3 of the tuning process is complete.

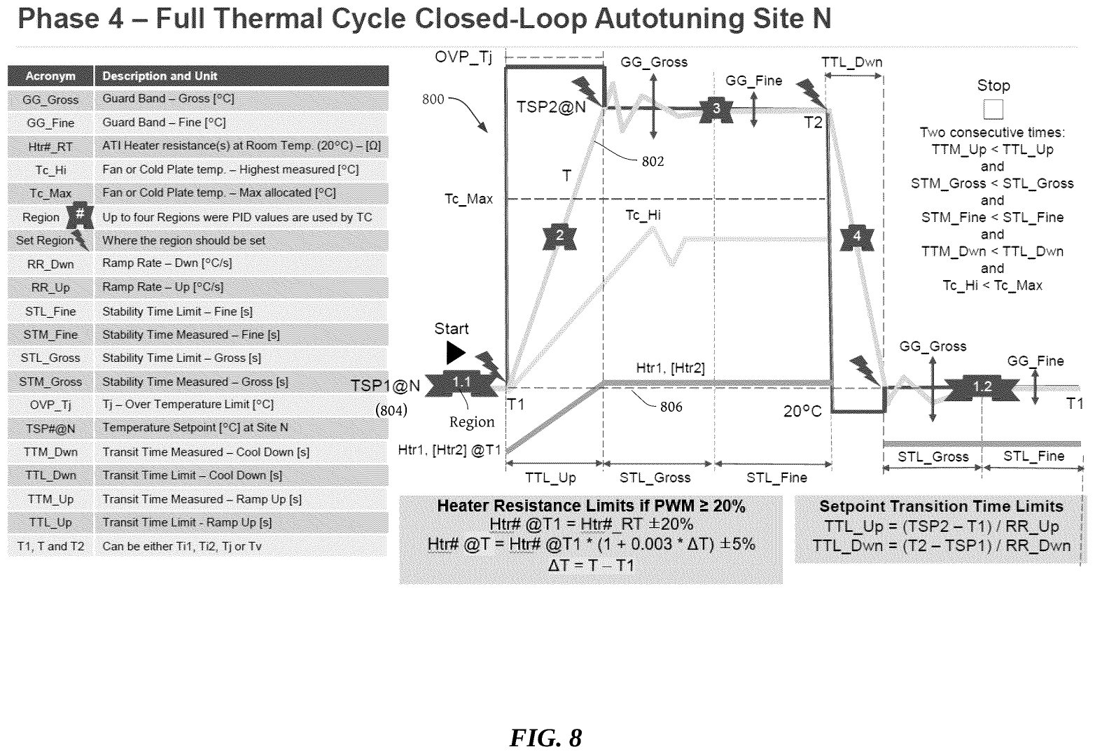

FIG. 8 is a graph depicting the fourth phase 800 of an exemplary automatic PID tuning process according to embodiments of the present invention. Phase 4 is a full thermal cycle closed-loop test including a period of stability at a reduced temperature following a falling temperature state. Only Region #1 PID values can be changed until the stability time is within the threshold limit at least two consecutive times.

Phase 4 begins like Phase 3 of the tuning process and includes the same test conditions as Phase 3 evaluated using heater resistance values 806; in addition, STM_Gross and STM_Fine are evaluated a second time when test site temperature 802 falls during region 4 and stabilizes during region 1.2 at temperature T1 corresponding to TSP1 804. STM_Gross<STL_Gross is satisfied when test site temperature 802 falls within guard band GG_Gross within the stability time limit STL_Gross, and STM_Fine<STL_Fine is satisfied when test site temperature 802 falls within fine guard band GG_Fine within the fine stability time limit STL_Fine. Phase 4 of the tuning process is complete these conditions have been satisfied by two consecutive successful tests.

FIG. 9 is a flowchart depicting an exemplary sequence of computer implemented steps of a process 900 for automatically tuning a PID controller for performing thermal control during device testing according to embodiments of the present invention. Process 900 can be performed independently and in parallel for multiple test sites by using a test board (e.g., a Burn-in Interface Board BIB or System Level Test SLT Test Interface Board TIB).

At step 902, an initial set of PID values are accessed for programing or executing functions of a PID controller to perform PID autotuning for a device under test. The PID controller can be coupled to a thermal controller, for example, that controls one or more heaters from an Active thermal Interposer (ATI) if present and cooling components from a cold plate or fan. The PID values can include values for driving a primary ATI heater, a secondary ATI heater, a fan or PVO PWM driven, and a dormant PID used to protect hardware during testing/tuning. According to some embodiments, the initial PID controller values are selected based on predefined test criteria (e.g., fan or cold plate operating temperature limit, stabilization, ramp up and cool down times).

At step 904, the initial set of PID values are applied to the PID controller to test the DUT and determine one or more responses of the DUT (e.g., temperature, stabilization time, ramp up time, etc.). The response(s) of the DUT can be evaluated against predetermined metrics (e.g., acceptance criteria) to determine if the PID values used to program the PID controller result in a pass or failure. The testing method and predetermined criteria can be determined according to requirements of a test phase, according to embodiments. Testing the DUT can include different test regions that evaluate different thermal characteristics, such as ramp up, stabilization, cool down, and full thermal cycle testing.

At step 906, the PID controller values are automatically adjusted (“tuned”) based on the response of the DUT to achieve a predefined performance metric. If the PID values applied in step 904 resulted in a passed test, the adjustment of step 906 can be skipped. According to embodiments, steps 904 and 906 can be repeated until the PID controller values result in a successful test, until multiple tests are passed consecutively, or until a threshold number of tests have been performed, for example.

At step 908, the PID controller values are stored in a memory associated with the DUT site (e.g., in a memory of the test site, test system, remote server, etc.). The stored PID values can then be used for thermal control during future DUT testing.

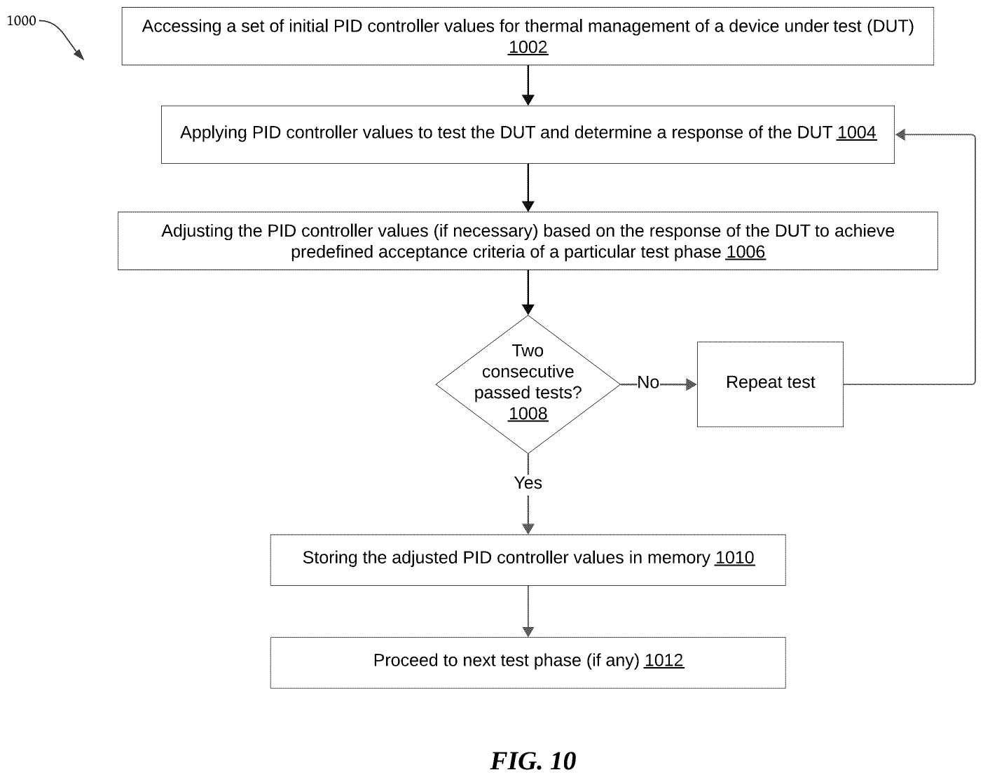

FIG. 10 is a flowchart depicting an exemplary sequence of computer implemented steps of a process 1000 for automatically tuning a PID controller for performing thermal control using a test sequence including multiple test phases with different testing methods/criteria according to embodiments of the present invention. For example, a first testing phase can include a time sensitive ramp up during high temperature closed-loop PID autotuning, and a second testing phase, performed after the first testing phase is passed, can include a time sensitive stability requirement during high temperature closed-loop PID autotuning.

At step 1002, an initial set of PID values are accessed for programing or executing functions of a PID controller to perform PID autotuning of a device under test. The PID controller can be coupled to a thermal controller, for example, that controls one or more heaters from ATI if present and cooling components from fan or cold plate. The PID values can include values for driving a primary ATI heater, a secondary ATI heater, a fan or PVO PWM driven, and a dormant PID used to protect hardware during testing/tuning. According to some embodiments, the initial PID controller values are selected based on predefined test criteria (e.g., fan or cold plate operating temperature limit, stabilization, ramp up and cool down times).

At step 1004, the initial set of PID values are applied to the PID controller to test the DUT and determine one or more responses/results of the DUT (e.g., temperature, stabilization time, ramp up and cool down times). The response(s) of the DUT can be evaluated against predetermined metrics (e.g., acceptance criteria) to determine if the PID values used to program the PID controller result in a pass or failure. The testing method and predetermined criteria are typically determined according to requirements of the current test phase. Testing the DUT can include different test regions that evaluate different thermal characteristics, such as ramp up, stabilization, cool down, and full thermal cycle testing.

At step 1006, the PID controller values are automatically adjusted (“tuned”) based on the response of the DUT to achieve a predefined performance metric of the current test phase. If the PID values applied in step 1004 resulted in a passed test, the adjustment of step 1006 can be skipped.

At step 1008, process 1000 determines if two consecutive tests of the current test phase have been passed by a DUT using the PID controller values. When two successful tests have been passed, process 1000 proceeds to step 1010. When two successful tests have not been passed, process 1000 returns to step 1004 to repeat the test by applying the PID controller values to again test the DUT.

At step 1010, after two consecutive tests have passed the requirements of the test phase, the PID controller values are stored in a memory associated with the DUT site (e.g., in a memory of the test site, test system, remote server, etc.). The stored PID values can then be used for thermal control during future DUT testing.

At step 1012, the tuning process 1000 is repeated starting at step 1002 for the next test phase (if any). When there are no further test phases, tuning process 1000 ends.

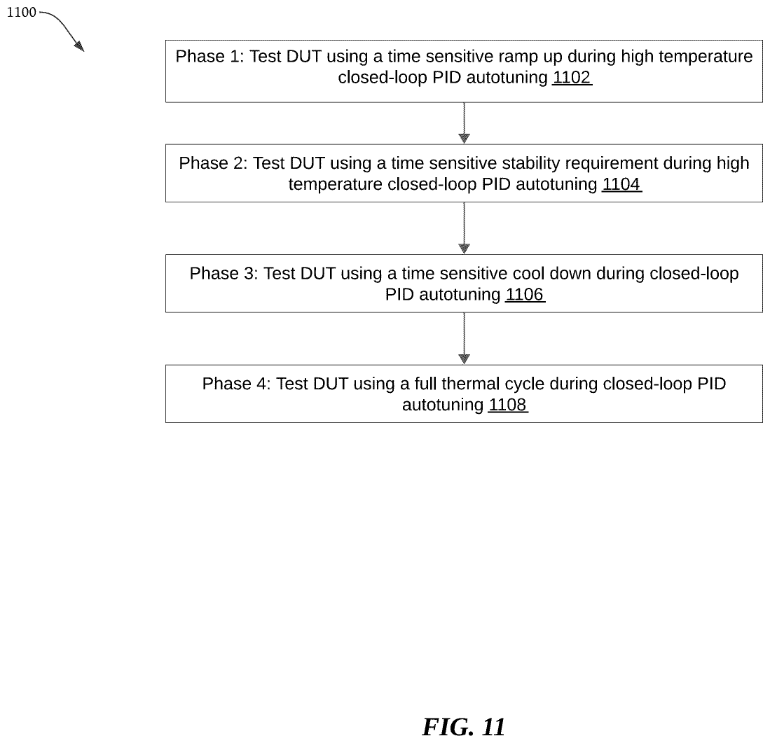

FIG. 11 is a flowchart depicting an exemplary sequence of computer implemented steps of a process 1100 for automatically tuning a PID controller for performing thermal control using a test sequence including four exemplary test phases according to embodiments of the present invention.

In the example of FIG. 11, Phase 1 (1102) involves initiating a period of temperature rise to assess the dynamic response of the system. This phase serves to understand how quickly and effectively the thermal control system can react to an increase in temperature of the device under test (DUT) or the Active Thermal Interposer (ATI). Phase 2 (1104) performs an extended temperature rise before allowing the DUT or ATI to stabilize at the set temperature to evaluate the steady-state performance and ability to maintain a consistent temperature under test conditions. In Phase 3 (1106), the process involves inducing a controlled temperature fall from the stabilized set temperature, providing insight into the system's cooling efficiency and how it handles decreases in thermal conditions. Phase 4 (1108) focuses on maintaining stability at a reduced temperature during a complete thermal cycle, testing the system's ability to sustain temperatures after falling back to initial thermal conditions. According to some embodiments, each test phase is repeated until PID values pass the requirements of the test phase two consecutive times.
1. In some embodiments, a test system for device under test (DUT) testing comprises a test board comprising a plurality of test sites operable to receive a plurality of devices under test (DUTs) for testing, and a cooling system comprising a PID (Proportional-Integral-Derivative) controller, wherein the PID controller is operable to automatically perform an adaptive PID tuning process to test the plurality of DUTs operable to be disposed in the test sites.
2. The test system of clause 1, wherein the PID controller is further operable to automatically adjust PID controller values for the plurality of DUTs based on a response measurement to achieve a target performance metric based on adjusted PID controller values.
3. The test system of clause 1 or 2, wherein the PID controller is further operable to store the adjusted PID controller values in a memory associated with a respective test site.
4. The test system of any clause 1-3, wherein the adaptive PID tuning process comprises accessing a set of initial PID controller values, applying the set of initial PID controller values to test the plurality of DUTs and to determine responses of the plurality of DUTs, adjusting the PID controller values based on the responses of the plurality of DUTs to achieve a predefined performance metric, and storing adjusted PID controller values in a memory associated with the plurality of test sites that receives the plurality of DUTs during testing.
5. The test system of any clause 1-4, wherein the PID controller values for the plurality of DUTs are tuned in parallel, and wherein the DUTs are tested and tuned independently.
6. The test system of any clause 1-5, further comprising a thermal controller communicatively coupled to the PID controller, wherein the thermal controller is operable to manage temperature conditions of the test board.
7. The test system of any clause 1-6, wherein the thermal controller is further operable to dynamically apply PID values provided by the PID controller.
8. The test system of any clause 1-7, wherein the thermal controller is further operable to perform temperature control using a DUT Temperature Feedback mode that functions to maintain conditions based on a temperature set point (TSP).
9. The test system of any clause 1-8, wherein the DUT Temperature Feedback mode functions to maintain, based on the TSP, at least one of a DUT temperature, and a thermal test vehicle (TTV) temperature.
10. The test system of any clause 1-9, wherein the thermal controller is further operable to perform temperature control using an Active Thermal Interposer (ATI) Temperature Feedback mode that functions to maintain an ATI temperature based on a temperature set point (TSP).
11. In some embodiments, an apparatus for tuning PID controller values, the apparatus comprises a memory for storing PID controller values, a temperature probe operable to determine a thermal response of a DUT to the PID controller values, and a PID controller operable to execute an adaptive PID tuning process comprising adjusting and storing the PID controller values based on the thermal response and test criteria.
12. The apparatus of any clause 11, further comprising a thermal controller communicatively coupled to the PID controller, wherein the thermal controller is operable to manage temperature conditions within the test environment.
13. The apparatus of any clause 11-12, wherein the thermal controller is further operable to dynamically apply PID values provided by the PID controller.
14. The apparatus of any clause 11-13, wherein the thermal controller is further operable to perform temperature control using a DUT Temperature Feedback mode that functions to maintain DUT thermal conditions based on a temperature set point (TSP).
15. The apparatus of any clause 11-14, wherein the DUT Temperature Feedback mode functions to maintain, based on the TSP, at least one of DUT temperature, and thermal test vehicle (TTV).
16. The apparatus of any clause 11-16, wherein the thermal controller is further operable to perform temperature control using an Active Thermal Interposer (ATI) Temperature Feedback mode that functions to maintain an ATI temperature based on a temperature set point (TSP).
17. In some embodiments, a method of automatically tuning PID (Proportional-Integral-Derivative) controller values for a tester system comprises accessing a set of initial PID controller values for testing a device under test (DUT), applying the set of initial PID controller values to test the DUT and determine a response of the DUT to the testing, adjusting the initial PID controller values based on the response of the DUT to achieve a predefined performance metric and to generate adjusted PID controller values, and storing the adjusted PID controller values in a memory associated with a DUT test site that receives the DUT during the testing.
18. The method of clause 17, wherein the applying the set of initial PID controller values to test the DUT and to determine a response of the DUT comprises testing a plurality of DUTs in parallel to determine a plurality of DUT responses.
19. The method of clause 17 or 18, further comprising testing the DUT using a DUT Temperature Feedback mode that functions to maintain DUT thermal conditions based on a temperature set point (TSP).
20. The method of any clause 17-19, further comprising testing the DUT using an Active Thermal Interposer (ATI) Temperature Feedback mode that functions to maintain an ATI temperature based on a temperature set point (TSP).

In sum, the disclosed techniques overcome the limitations of traditional methods by providing a flexible and adaptable automatic PID tuning process, ensuring precise, consistent settings across multiple test sites without requiring manual intervention by a technician. Moreover, embodiments disclosed herein support highly scalable parallel autotuning, significantly accelerating the testing process compared to sequential or manual methods.

At least one technical advantage of the disclosed techniques is that operational power consumption is reduced significantly by optimizing PID settings. Moreover, testing efficiency is improved through automation, eliminating the need for manual tuning, which is time consuming, inefficient, and prone to error.

Any and all combinations of any of the claim elements recited in any of the claims and/or any elements described in this application, in any fashion, fall within the contemplated scope of the present invention and protection.

The descriptions of the various embodiments have been presented for purposes of illustration but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. While the preceding is directed to embodiments of the present disclosure, other and further embodiments of the disclosure may be devised without departing from the basic scope thereof, and the scope thereof is determined by the claims that follow.

Embodiments of the present invention are thus described. While the present invention has been described in particular embodiments, it should be appreciated that the present invention should not be construed as limited by such embodiments, but rather construed according to the following claims.

What is claimed is:

1. A test system for device testing, the system comprising:
a test board comprising a plurality of test sites operable to receive a plurality of devices under test (DUTs) for testing; and
a cooling system comprising a PID (Proportional-Integral-Derivative) controller, wherein the PID controller is operable to automatically perform an adaptive PID tuning process to test the plurality of DUTs operable to be disposed in the test sites.

2. The test system of claim 1, wherein the PID controller is further operable to automatically adjust PID controller values for the plurality of DUTs based on a response measurement to achieve a target performance metric based on adjusted PID controller values.

3. The test system of claim 2, wherein the PID controller is further operable to store the adjusted PID controller values in a memory associated with a respective test site.

4. The test system of claim 2, wherein the adaptive PID tuning process comprises:
accessing a set of initial PID controller values;
applying the set of initial PID controller values to test the plurality of DUTs and to determine responses of the plurality of DUTs;
adjusting the PID controller values based on the responses of the plurality of DUTs to achieve a predefined performance metric; and
storing adjusted PID controller values in a memory associated with the plurality of test sites that receives the plurality of DUTs during testing.

5. The test system of claim 4, wherein the PID controller values for the plurality of DUTs are tuned in parallel, and wherein the DUTs are tested and tuned independently.

6. The test system of claim 2, further comprising a thermal controller communicatively coupled to the PID controller, wherein the thermal controller is operable to manage temperature conditions of the test board.

7. The test system of claim 6, wherein the thermal controller is further operable to dynamically apply PID values provided by the PID controller.

8. The test system of claim 7, wherein the thermal controller is further operable to perform temperature control using a DUT Temperature Feedback mode that functions to maintain conditions based on a temperature set point (TSP).

9. The test system of claim 8, wherein the DUT Temperature Feedback mode functions to maintain, based on the TSP, at least one of: a DUT temperature; and a thermal test vehicle (TTV) temperature.

10. The test system of claim 7, wherein the thermal controller is further operable to perform temperature control using an Active Thermal Interposer (ATI) Temperature Feedback mode that functions to maintain an ATI temperature based on a temperature set point (TSP).

11. An apparatus for tuning PID controller values, the apparatus comprising:
a memory for storing PID controller values;
a temperature probe operable to determine a thermal response of a DUT to the PID controller values; and
a PID controller operable to execute an adaptive PID tuning process comprising adjusting and storing the PID controller values based on the thermal response and test criteria.

12. The apparatus of claim 11, further comprising a thermal controller communicatively coupled to the PID controller, wherein the thermal controller is operable to manage temperature conditions within the test environment.

13. The apparatus of claim 12, wherein the thermal controller is further operable to dynamically apply PID values provided by the PID controller.

14. The apparatus of claim 13, wherein the thermal controller is further operable to perform temperature control using a DUT Temperature Feedback mode that functions to maintain DUT thermal conditions based on a temperature set point (TSP).

15. The apparatus of claim 14, wherein the DUT Temperature Feedback mode functions to maintain, based on the TSP, at least one of: DUT temperature; and thermal test vehicle (TTV).

16. The apparatus of claim 13, wherein the thermal controller is further operable to perform temperature control using an Active Thermal Interposer (ATI) Temperature Feedback mode that functions to maintain an ATI temperature based on a temperature set point (TSP).

17. A method of automatically tuning PID (Proportional-Integral-Derivative) controller values for a tester system, the method comprising:
accessing a set of initial PID controller values for testing a device under test (DUT);
applying the set of initial PID controller values to test the DUT and determine a response of the DUT to the testing;
adjusting the initial PID controller values based on the response of the DUT to achieve a predefined performance metric and to generate adjusted PID controller values; and
storing the adjusted PID controller values in a memory associated with a DUT test site that receives the DUT during the testing.

18. The method of claim 17, wherein the applying the set of initial PID controller values to test the DUT and to determine a response of the DUT comprises testing a plurality of DUTs in parallel to determine a plurality of DUT responses.

19. The method of claim 17, further comprising testing the DUT using a DUT Temperature Feedback mode that functions to maintain DUT thermal conditions based on a temperature set point (TSP).

20. The method of claim 17, further comprising testing the DUT using an Active Thermal Interposer (ATI) Temperature Feedback mode that functions to maintain an ATI temperature based on a temperature set point (TSP).
